(19) United States
(12) Patent Application Publication
(10) Pub. No.: US 2025/0089347 A1
(43) Pub. Date: Mar. 13, 2025

(54) CIRCULAR-SHAPED RESISTOR

(71) Applicant: International Business Machines Corporation, Armonk, NY (US)

(72) Inventors: Ashim Dutta, Clifton Park, NY (US); Brandon Noland Canedy, Cohoes, NY (US); Chih-Chao Yang, Glenmont, NY (US); Shravana Kumar Katakam, Lehi, UT (US)

(21) Appl. No.: 18/465,376

(22) Filed: Sep. 12, 2023

(51) Int. Cl. H01L 27/08; H01L 21/02; H01L 21/311; H01L 21/3205; H01L 21/3213

(52) U.S. Cl. CPC H10D 84/209; H01L 21/02271; H01L 21/31116; H01L 21/32051; H01L 21/32136; H10D 1/474

(57) ABSTRACT

A structure that includes a plurality of circular metal elements that are concentrically arranged and connected through a plurality of metal connectors, wherein the structure forms a circular resistor.

### BACKGROUND

The present disclosure relates to semiconductor fabrication. More particularly, the present disclosure provides a circular-shaped resistor, and a method of forming the circular-shaped resistor.

Generally, semiconductor devices include a plurality of circuits which form an integrated circuit (IC) fabricated on a semiconductor substrate. A complex network of signal paths will normally be routed to connect the circuit elements distributed on the surface of the substrate.

### SUMMARY

According to some embodiments of the disclosure, there is provided a structure. The structure includes a plurality of circular metal elements that are concentrically arranged and connected through a plurality of metal connectors, wherein the structure forms a circular resistor.

According to some embodiments of the disclosure, there is provided a device. The device includes a substrate including a layer of dielectric material, and a circular resistor embedded in the layer of dielectric material, wherein the circular resistor includes a plurality of circular metal elements that are concentrically arranged and connected through a plurality of metal connectors.

According to some embodiments of the disclosure, there is provided a method of forming a structure. The method includes: providing a substrate including a dielectric material, etching the dielectric material in order to form a dielectric pillar, depositing a first conformal metal liner on the substrate and the dielectric pillar, and etching the first conformal metal liner from the substrate and leaving behind a first circular metal element. The method further includes: depositing a first layer of conformal dielectric material on the substrate and the first circular metal element, etching the first layer of conformal dielectric material from the substrate and leaving behind a first dielectric material ring, depositing a second conformal metal liner on the substrate and the first dielectric material ring, and etching the second conformal metal liner from the substrate and leaving behind a second circular metal element. The method additionally includes: cutting the first circular metal element and the second circular metal element, and forming a first connector that attaches the first circular metal element to the second circular metal element.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1A illustrates a top, see-through or top-down view of a resistor structure, in accordance with embodiments of the disclosure.

FIG. 1B illustrates a cross-sectional, see-through view of the resistor structure of FIG. 1A with a cross-section taken at line 1B in FIG. 1A, in accordance with embodiments of the disclosure.

FIG. 2A illustrates a top, see-through or top-down view of a resistor structure, in accordance with embodiments of the disclosure.

FIG. 2B illustrates a cross-sectional, see-through view of the resistor structure of FIG. 2A with a cross-section taken at line 2B in FIG. 2A, in accordance with embodiments of the disclosure.

FIGS. 3-10B illustrate cross-sectional or top views of a resistor device, after a series of operations of a process are performed, in order to form the resistor device, in accordance with embodiments of the disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to semiconductor fabrication. More particularly, the present disclosure provides a circular-shaped resistor, and a method of forming the circular-shaped resistor. While the present disclosure is not necessarily limited to such applications, various aspects of the disclosure can be appreciated through a discussion of various examples using this context.

A resistor is one of the most common electrical components and is used in almost every electrical device. In semiconductor device fabrication, it is well known to have thin film resistors embedded in the back-end-of-line (BEOL) structures of an IC chip through either a damascene approach or a subtractive etch method, for example. The BEOL thin film resistors are preferred over other types of resistors because of the lower parasitic capacitance.

Integration schemes used to fabricate resistor components within an interconnect structure fall into two primary categories. In the first integration scheme, a thin film resistor is formed by etching on top of an insulator. A metallic layer is deposited on top of the resistive layer and is used to protect the resistive layer from being damaged during the sequential etching process. After the resistor has been defined, the underneath dielectric is then patterned and etched to define the interconnect pattern. Finally, a metallic layer for the interconnect is deposited, patterned, and etched. This process presents challenges because, although the protective layer is capable of protecting the resistive layer, the provided protection is limited, and the resistive layer may still get damaged during the etching process. This approach also requires extra layers, which adds cost and complexity. In the second integration scheme, a thin film resistor is formed by etching on top of an insulator. An interlevel dielectric is then deposited, followed by patterning and etching processes to define an upper-level interconnect structure with vias connected to the underneath thin film resistor. A planarization process is usually required after deposition of the interlevel dielectric material in order to compromise any possible topography related issues caused by the underneath resistors. The planarization process adds expense.

Semiconductor processing for the fabrication of IC chips continues to evolve towards smaller dimensions. Extendibility of the resistors with the continual scaling of the feature size, has resulted in the available IC chip area for the resistor element being more limited and a challenge in fabrication of the IC chip. In view of the foregoing, there is a need in the art for a solution to the problems of any related art.

Exemplary embodiments of the disclosure will now be discussed in further detail with regard to fabricating a resistor and, in particular, a circular-shaped resistor. This new structure contains multiple concentric circular-shaped high density resistor elements.

There are advantages to the novel structure of resistor described herein. For example, the resistor structure can be used at wide range of critical dimensions and can be scaled to smaller dimensions.

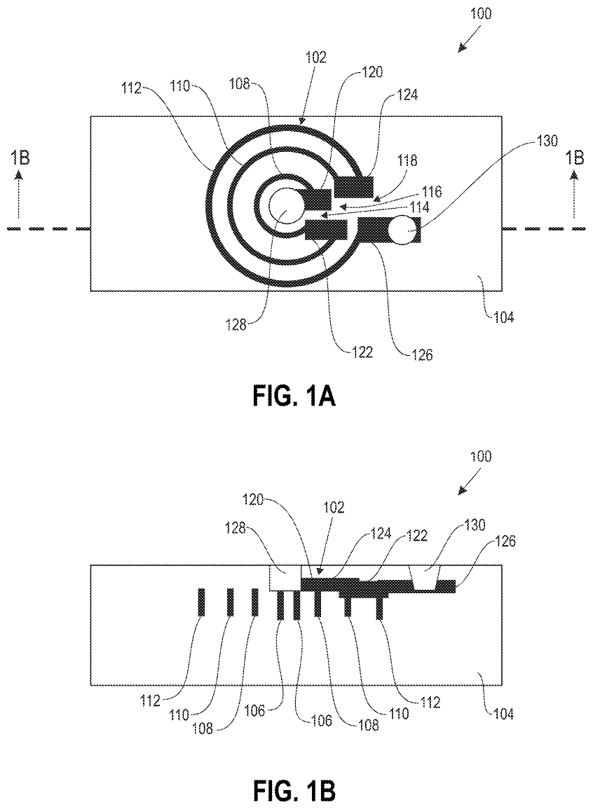

A resistor structure 100 including have a first circular-shaped resistor 102, and in some embodiments also a second circular-shaped resistor 202, in accordance with this disclosure, is represented in FIGS. 1A through 10B. The portion of the circuit board includes a dielectric material 104. The first circular-shaped resistor 102, and the second circular-shaped resistor 202 are formed around and/or within the dielectric material 104.

FIG. 1A illustrates a top, see-through or top-down view of a resistor structure 100 that includes the first circular-shaped resistor 102, in accordance with embodiments of the disclosures. FIG. 1B illustrates a cross-sectional, see-through view of the resistor structure 100 of FIG. 1A with a cross-section taken at line 1B in FIG. 1A, in accordance with embodiments of the disclosure. The circular-shaped resistor 102 can include four (4) concentrically arranged circular metal elements, for example, which include an innermost first circular metal element 106 (shown in FIG. 1A) surrounded by a second circular metal element 108 that is, in turn, surrounded by a third circular metal element 110, that is, in turn, surrounded by a fourth circular metal element 112. The four (4) circular metal elements 106, 108, 110, 112 can be formed of a thin metal liner material that are incomplete circles and can include cuts (or openings). In FIG. 1A, a first cut 114 can be included in the second circular metal element 108, a second cut 116 can be included in the third circular metal element 110, and a third cut 118 can be included in the fourth circular metal element 112. At terminating ends of the second, third and fourth circular metal elements 108, 110, 112, there can be metal connectors. A first metal connector 120 is shown attached to a first end of the second circular metal element 108. A second metal connector 122 is shown connected to a second end of the second circular metal element 108 and to a first end of the third circular metal element 110. A third metal connector 124 is shown connected to a second end of the third circular metal element 110 and a first end of the fourth circular metal element 112. A fourth metal connector 126 is connected to a second end of the fourth circular metal element 112. As shown, there can be two electrodes attached to the connectors, specifically a first electrode 128 is connected to the first connector 120, and a second electrode 130 is connected to the fourth connector 126.

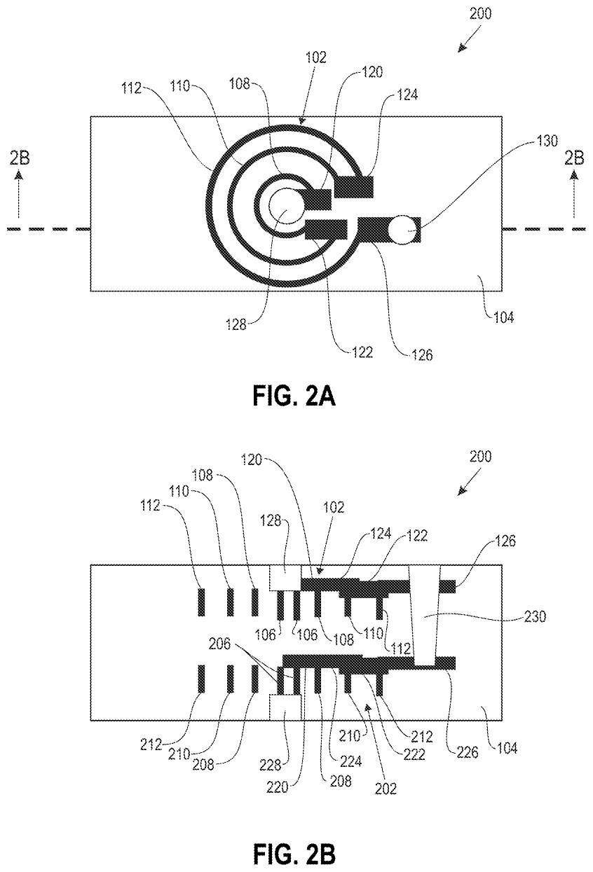

FIG. 2A illustrates a top, see-through or top-down view of a resistor structure 200 that includes the first circular-shaped resistor 102 and the second circular-shaped resistor 202, in accordance with embodiments of the disclosures. FIG. 2B illustrates a cross-sectional, see-through view of the resistor structure 200 of FIG. 2A with a cross-section taken at line 2B in FIG. 2A, in accordance with embodiments of the disclosure. As shown, the first circular-shaped resistor 102 and the second circular-shaped resistor 202 are stacked, meaning the two resistors are arranged perpendicular with respect to each other as shown in the resistor structure 200. The first circular-shaped resistor 102 is an upper resistor and the second circular-shaped resistor 202 is a lower resistor. The figures are drawn with the first and second circular-shaped resistors 102, 202 extending in a nominally horizontal plane, and for purposes of description, that orientation will be used, it being recognized that when the first and second circular-shaped resistors 102, 202 are ultimately in a larger assembly, the assembly, and hence the first and second circular-shaped resistors 102, 202, may be in any orientation.

The second circular-shaped resistor 202 is similar to the first circular-shaped resistor 102 shown in FIGS. 1A-1B. The description above of the first circular-shaped resistor 102 applies to the second circular-shaped resistor 102 in FIGS. 2A-2B as well. The only exception to the description above is that the second electrode 130 (shown in FIG. 1A) is not included in the first circular-shaped resistor 102, and a third electrode 230 is included instead and extends between the first circular-shaped resistor 102 and the second circular-shaped resistor 202, as shown in FIG. 2B.

The resistor structure 200 includes the second circular-shaped resistor 202, which can include four (4) concentrically arranged circular metal elements, for example, which include an innermost first circular metal element 206 (shown in FIG. 2B) surrounded by a second circular metal element 208 that is, in turn, surrounded by a third circular metal element 210, that is, in turn, surrounded by a fourth circular metal element 212. The four (4) circular metal elements 206, 208, 210, 212 can be formed of a thin metal liner material that are nearly complete (i.e., incomplete) circles and can include cuts (or openings). A first cut (not visible in FIG. 2B) can be included in the second circular metal element 208, a second cut (not visible in FIG. 2B) can be included in the third circular metal element 210, and a third cut (not visible in FIG. 2B) can be included in the fourth circular metal element 212. At terminating ends of the second, third and fourth circular metal elements 208, 210, 212, there can be metal connectors. A first metal connector 220 is shown attached to a first end of the second circular metal element 208. A second metal connector 222 is shown connected to a second end of the second circular metal element 208 and to a first end of the third circular metal element 210. A third metal connector 224 is shown connected to a second end of the third circular metal element 210 and a first end of the fourth circular metal element 212. A fourth metal connector 226 is connected to a second end of the fourth circular metal element 212. As shown, there can be two electrodes attached to the connectors, specifically a first electrode 228 is connected to the first connector 220, and a second electrode 230 is connected to the fourth connector 226, and to the first circular-shaped resistor 102.

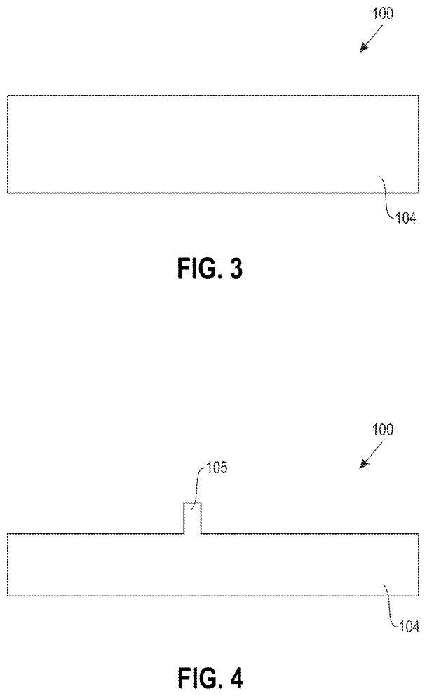

FIGS. 3-10B illustrate cross-sectional or top views of the resistor structure 100, after a series of operations of a process are performed, in order to form the resistor structure 100, in accordance with embodiments of the disclosure. As in FIG. 3, a dielectric material 104 can be deposited using standard deposition techniques used in semiconductor back end-of-line (BEOL) processing. The dielectric material 104 can include any suitable insulator material such as, for example, hydrogenated silicon oxycarbide (SiCOH), SILK® available from Dow Chemical, porous dielectrics, etc.

Next, as shown in FIG. 4, the dielectric material 104 (of FIG. 3) can be etched away using conventional dry/plasma etching processes, for example. The etching can be performed in order to form a dielectric pillar 105 on a top surface of the dielectric material 104, as shown.

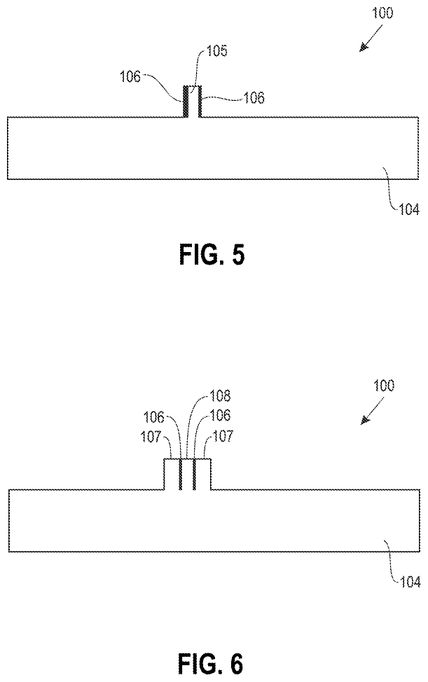

As shown in FIG. 5, a thin layer of conformal metal material can be deposited on the dielectric material 104 including the dielectric pillar 105 (of FIG. 4). The conformal metal material can be a resistor material such as: tungsten (W), titanium nitride (TiN) or tantalum nitride (TaN), for example, which can be infused with at least one of silicon (Si), nitrogen (N₂), or aluminum. Each of these materials provides a high resistivity metal resistor. The deposition process that can be used to deposit the thin layer of the conformal metal material includes, e.g., atomic layer deposition (ALD), plasma enhanced atomic layer deposition (PEALD), etc. In FIG. 5, the conformal metal material is shown after a dry/plasma etching process was used to remove the conformal metal material from all horizontal surfaces and leaves behind a thin conformal metal liner, which forms the first circular metal element 106 (shown in FIG. 1A), located on the dielectric pillar 105.

Next, in FIG. 6, a layer of dielectric material, such as that described above, has been deposited atop the resistor structure 100 (of FIG. 5), and is shown etched back. A circular layer of dielectric material 107 remains after etching and is shown circumferentially surrounding the first circular metal element 106 (shown in FIG. 1A).

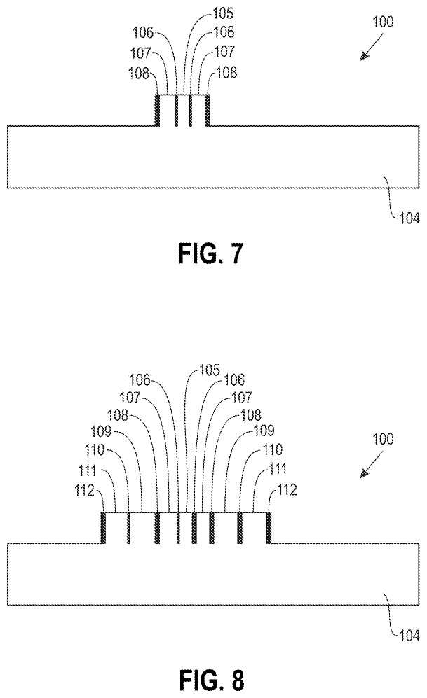

In FIG. 7, the resistor structure 100 (of FIG. 6) is shown after a second conformal metal layer has been deposited and etched back, as described above. After etching, a second thin conformal metal liner, which forms the second circular metal element 108 (shown in FIG. 1A), is left behind and circumferentially surrounds the circular layer of dielectric material 107.

In FIG. 8, the resistor structure 100 (of FIG. 7) is shown after two (2) additional circular layers of dielectric material and two (2) additional thin conformal metal liners are added. A layer of dielectric material, such as that described above, has been deposited atop the resistor structure 100 (of FIG. 7), and is shown etched back. A second circular layer of dielectric material 109 remains after etching and is shown circumferentially surrounding the second circular metal element 108. A third conformal metal layer has been deposited and etched back, as described above. After etching, a third thin conformal metal liner, which forms the third circular metal element 110 (shown in FIG. 1A), is left behind and circumferentially surrounds the second circular layer of dielectric material 109. In the same figure, another layer of dielectric material, such as that described above, has been deposited atop the resistor structure 100 (of FIG. 7), and is shown etched back. A third circular layer of dielectric material 111 remains after etching and is shown circumferentially surrounding the third circular metal element 110. A fourth conformal metal layer has been deposited and etched back, as described above. After etching, a fourth thin conformal metal liner, which forms the fourth circular metal element 112 (shown in FIG. 1A), is left behind and circumferentially surrounds the third circular layer of dielectric material 111.

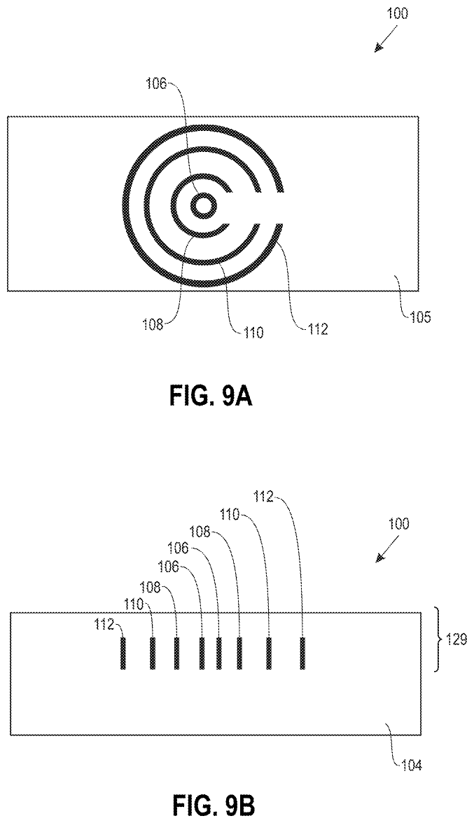

In FIGS. 9A-9B, the resistor structure 100 (of FIG. 8) is shown in a cross-sectional view and a top-down view, respectively after an operation in which the second, third and fourth circular metal elements 108, 110, 112 are cut. The second, third and fourth circular metal elements 108, 110, 112 can be cut using, for example, a dry/plasma etch process. The figures also show the resistor structure 100 after a top layer of dielectric material 129 was deposited atop the over the second, third and fourth circular metal elements 108, 110, 112 using standard deposition techniques, such as chemical vapor deposition (CVD).

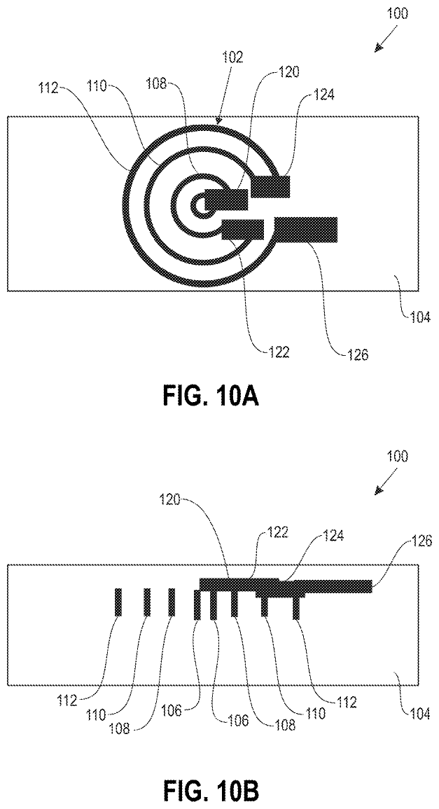

In FIGS. 10A-10B, the resistor structure 100 (of FIG. 8) is shown in a cross-sectional view and a top down view, respectively after an operation in which metal connector patterning and fill has taken place in order to form the first metal connector 120, the second metal connector 122, the third metal connector 124 and the fourth metal connector 126 at terminating ends of the second, third and fourth circular metal elements 108, 110, 112. In order to form the connectors 120, 122, 124 126, a dielectric layer like silicon dioxide can be deposited and patterned using lithographic and plasma etch techniques and then filled with metal contacts using standard deposition techniques, such as physical vapor deposition (PVD) or atomic layer deposition (ALD). Next, a chemical mechanical polishing (CMP) process can be used to remove any excess metal form the connectors 120, 122, 124, 126. The first metal connector 120 is shown attached to a first end of the second circular metal element 108. The second metal connector 122 is shown connected to a second end of the second circular metal element 108 and to a first end of the third circular metal element 110. The third metal connector 124 is shown connected to a second end of the third circular metal element 110 and a first end of the fourth circular metal element 112. The fourth metal connector 126 is connected to a second end of the fourth circular metal element 112.

In a process of forming the resistor structure 100 of FIGS. 1A-1B, electrodes are formed after the resistor structure shown in FIGS. 10A-10B. The resistor structure 10 of FIGS. 1A-1B includes the electrodes 128, 130 using, for example, using a standard damascene process that can include oxide deposition, subsequent dry/plasma etch patterning followed by deposition and a CMP process.

In order to form the resistor structure 200 of FIGS. 2A-2B, the operations described above can be repeated again to forma stacked resistor including more than one resistor, such as the first resistor 102 and the second resistor 202 in resistor structure 200 (in FIGS. 2A-2B).

The embodiments of the present disclosure include a method of forming a first circular-shaped resistor (such as 102 in FIGS. 1A-1B) where a dielectric pillar (such as 105 in FIG. 4) is first formed and then a thin metal layer/liner is deposited using a conformal deposition (e.g., ALD, PEALD etc.) process. The thin metal layer/liner is deposited over the dielectric pillar (such as 105 in FIG. 5) and etched back is used to remove the liner from all horizontal surface and leave a first circular metal element (such as 106 in FIG. 5) behind. Another dielectric layer (such as the circular layer of dielectric material 107) is then deposited and etched back. Another layer of metal is then deposited and etched back. This sequence of metal layer and dielectric layer formation can be repeated to form as many circular rings (such as circular metal elements 108, 110, 112) as needed. Therefore, the number of circular rings or circular metal elements are not limited to those shown in the figures and described herein above. A portion of each of the circular metal elements can be cut using etching processes, for example, and filled with dielectric material (such as 129 in FIG. 9B). Electrodes (such as 128, 130 in FIG. 1A) can be formed using a damascene process. These processes can be repeated to form another layer of circular resistors to form a stacked resistor including more than one resistor (such as 102 and 202 in FIG. 2B). Thus, the embodiments of the present disclosure include a method of forming a stacked resistor, such as resistor structure 200 in FIG. 2B.

The embodiments of the present disclosure include a circular resistor structure (such as circular-shaped resistor 102 in FIG. 1A) including multiple concentrically arranged circular thin metal elements (such as circular metal elements 108, 110, 112 in FIG. 1A) connected through metal connectors (such as 120, 122, 124 in FIG. 1A). Each of the plurality of concentrically-arranged circular metal elements (such as circular metal elements 108, 110, 112 in FIG. 1A) can include a cut (such as first cut 114, second cut 116 and third cut 118 in FIG. 1A) at one location each where it can be connected to adjacent concentrically-arranged circular metal elements through metal connectors (such as first metal connector 120, second metal connector 122, and third metal connector 124 in FIG. 1A). Separations between sets of two of the concentrically arranged circular metal elements can be the same or can vary. In other words, the thickness of the circular layers of dielectric material (such as 105, 107, 109 and 111 in FIG. 8) can vary or can be the same thickness. The thickness of the circular metal elements can vary or can be the same. The metal that is used to make up the circular metal elements can also vary of can be the same. The thickness of the metal connectors can be greater than the thickness of the circular metal elements.

The embodiments of the present disclosure can include a stacked resistor with multiple resistors (such as 102, 202 in FIG. 2B) including circular metal elements (such as circular metal elements 108, 110, 112 in FIG. 1A) that can be stacked to increase total resistance of the system without increasing area footprint. The stacked resistor (such as 200 in FIG. 2B) can include two separate levels of resistors including multiple concentrically arranged metal elements. The two (2) resistors, for example, can be connected using a vertical metal contact (such as electrode 230 in FIG. 2B). The multiple resistors can be made of different materials or can be the same material. The separation between (or distance between) the two levels of resistors can be comparable or greater than the thickness of the circular metal elements that make up the resistors.

It is to be understood that the various layers and/or regions shown in the accompanying drawings are not drawn to scale, and that one or more layers and/or regions of a type commonly used in complementary metal-oxide semiconductor (CMOS), fin field-effect transistor (FinFET), metal-oxide-semiconductor field-effect transistor (MOSFET), and/or other semiconductor devices, may not be explicitly shown in a given drawing. This does not imply that the layers and/or regions not explicitly shown are omitted from the actual devices. In addition, certain elements may be left out of particular views for the sake of clarity and/or simplicity when explanations are not necessarily focused on the omitted elements. Moreover, the same or similar reference numbers used throughout the drawings are used to denote the same or similar features, elements, or structures, and thus, a detailed explanation of the same or similar features, elements, or structures will not be repeated for each of the drawings.

The semiconductor devices and methods for forming same in accordance with embodiments of the present disclosure can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

The embodiments of the present disclosure can be used in connection with semiconductor devices that may require, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

1. A structure comprising:
a plurality of circular metal elements that are concentrically arranged and connected through a plurality of metal connectors, wherein the structure forms a circular resistor.

2. The structure of claim 1, wherein each of the plurality of circular metal elements includes a cut at one location where each of the plurality of circular metal elements is connected to an adjacent circular metal element of the plurality of circular metal elements through one of the plurality of metal connectors.

3. The structure of claim 2, wherein a distance between each of the plurality of circular metal elements and each of the adjacent circular metal elements is the same.

4. The structure of claim 1, wherein a thickness of each of the plurality of circular metal elements is the same.

5. The structure of claim 1, wherein each of the plurality of circular metal elements includes a same metal material.

6. The structure of claim 1, wherein each of the plurality of metal connectors has a thickness that is greater than a thickness of each of the plurality of circular metal elements.

7. The structure of claim 1, further comprising:
at least one electrode each attached to one of the plurality of metal connectors.

8. A device comprising:
a substrate including a layer of dielectric material; and
a circular resistor embedded in the layer of dielectric material, wherein the circular resistor includes a plurality of circular metal elements that are concentrically arranged and connected through a plurality of metal connectors.

9. The device of claim 8, further comprising:
a second circular resistor embedded in the layer of dielectric material below or above the circular resistor; and
an electrode connecting the circular resistor and the second circular resistor.

10. The device of claim 9, wherein the circular resistor and the second circular resistor are on different levels in the substrate and are stacked with the circular resistor on top of the second circular resistor.

11. The device of claim 8, wherein each of the plurality of circular metal elements includes a cut at one location where each of the plurality of circular metal elements is connected to an adjacent circular metal element of the plurality of circular metal elements through one of the plurality of metal connectors.

12. The device of claim 11, wherein a distance between each of the plurality of circular metal elements and each of the adjacent circular metal elements is the same.

13. The device of claim 8, wherein a thickness of each of the plurality of circular metal elements is the same.

14. The device of claim 8, wherein each of the plurality of circular metal elements includes a same metal material.

15. The device of claim 8, wherein each of the plurality of metal connectors has a thickness that is greater than a thickness of each of the plurality of circular metal elements.

16. The device of claim 8, further comprising:
at least one electrode each attached to one of the plurality of metal connectors.

17. A method of forming a structure, the method comprising:
providing a substrate including a dielectric material;
etching the dielectric material in order to form a dielectric pillar;
depositing a first conformal metal liner on the substrate and the dielectric pillar;
etching the first conformal metal liner from the substrate and leaving behind a first circular metal element;
depositing a first layer of conformal dielectric material on the substrate and the first circular metal element;
etching the first layer of conformal dielectric material from the substrate and leaving behind a first dielectric material ring;
depositing a second conformal metal liner on the substrate and the first dielectric material ring;
etching the second conformal metal liner from the substrate and leaving behind a second circular metal element;
cutting the first circular metal element and the second circular metal element; and
forming a first connector that attaches the first circular metal element to the second circular metal element.

18. The method of claim 17, the method further comprising:
depositing a second layer of conformal dielectric material on the substrate and the second circular metal element;
etching the second layer of conformal dielectric material from the substrate and leaving behind a second dielectric material ring;
depositing a third conformal metal liner on the substrate and the second dielectric material ring;
etching the third conformal metal liner from the substrate and leaving behind a third circular metal element;
cutting the third circular metal element; and
forming a second connector that attaches the second circular metal element to the third circular metal element.

19. The method of claim 18, the method further comprising:
depositing a third layer of conformal dielectric material on the substrate and the third circular metal element;
etching the third layer of conformal dielectric material from the substrate and leaving behind a third dielectric material ring;
depositing a fourth conformal metal liner on the substrate and the third dielectric material ring;
etching the fourth conformal metal liner from the substrate and leaving behind a fourth circular metal element;
cutting the fourth circular metal element; and
forming a third connector that attaches the third circular metal element to the fourth circular metal element.

20. The method of claim 19, the method further comprising:
forming at least one electrode connected to at least one of the first, the second and/or the third connector.
